(19) United States
(12) Patent Application Publication
(10) Pub. No.: US 2007/0287286 A1
(43) Pub. Date: Dec. 13, 2007

(54) Method for fabricating semiconductor device

(75) Inventors: Ki-Won Nam, Kyoungki-do (KR); Ky-Hyun Han, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/647,668

(22) Filed: Dec. 29, 2006

(30) Foreign Application Priority Data
Jun. 13, 2006 (KR) 2006-0053093

(51) Int. Cl. H01L 21/44

(52) U.S. Cl. 438/675

(57) ABSTRACT

A method for fabricating a semiconductor device includes forming an insulation layer over a substrate having a given structure, forming a hard mask pattern over the insulation layer, performing a main etch on the insulation layer with a high etch selectivity with respect to a hard mask pattern to form a preliminary contact hole, performing an overetch on the insulation layer with a low etch selectivity with respect to a hard mask pattern to form a contact hole, and forming a conductive layer and performing an etch-back process to form a contact filled in the contact hole.

### CROSS-REFERENCE TO RELATED APPLICATIONS

The present invention claims priority of Korean patent application number 10-2006-0053093, filed on Jun. 13, 2006, which is incorporated by reference in its entirety.

### BACKGROUND OF THE INVENTION

The present invention relates to a method for fabricating a semiconductor device, and more particularly to a method for forming a storage node contact hole in a semiconductor device.

In recent years, with the high integration of a semiconductor device, an overlap margin between upper and lower trenches as well as an interline spacing has decreased. Particularly, in a sub-90 nm highly integrated device, a contact overlap margin between a storage node contact hole and a storage node hole in which a storage node is formed has decreased, and a depth of the storage node contact hole has greatly increased. This causes a leaning phenomenon of the storage node hole, and thus a contact failure occurs between the storage node and the storage node contact as devices get closer to a wafer edge.

FIG. 1 illustrates a micrographic view of a typical overlap configuration of a storage node hole with a storage node contact hole. When forming a storage node hole over a storage node contact hole according to a typical method, the storage node hole is formed in a zig-zag shape such that the storage node hole is not aligned with the storage node contact hole but misaligned so as to lean to one side of the storage node contact hole, because there is not sufficient space between the storage node hole and the storage node contact hole. Thus, if the leaning phenomenon of the storage node hole occurs, a contact failure between the storage node contact and the storage node may be generated.

Consequently, according to the typical method, because of a small contact margin between a top portion of the storage node contact hole and a bottom portion of the storage node hole, an open fail occurs between the storage node contact formed in the storage node contact hole and the storage node formed in the storage node hole.

### SUMMARY OF THE INVENTION

Embodiments of the present invention are directed to provide a method for fabricating a semiconductor device capable of increasing a contact margin between a top portion of a storage node contact hole and a bottom portion of a storage node hole when defining the storage node hole.

In accordance with an aspect of the present invention, there is provided a method for fabricating a semiconductor device, including: forming an insulation layer over a substrate having a given structure; forming a hard mask pattern over the insulation layer; performing a main etch on the insulation layer with a high etch selectivity with respect to a hard mask pattern to form a preliminary contact hole; performing an overetch on the insulation layer with a low etch selectivity with respect to a hard mask pattern to form a contact hole; and forming a conductive layer and performing an etch-back process to form a contact filled in the contact hole.

In accordance with another aspect of the present invention, there is provided a method for fabricating a semiconductor device, including: forming an oxide layer for insulation over a substrate having a given structure; forming a hard mask nitride-based pattern over the oxide layer; performing a main etch on the oxide layer with a high etch selectivity with respect to the hard mask nitride-based pattern to form a preliminary storage node contact hole; performing an overetch on the oxide layer with a low etch selectivity with respect to a hard mask nitride-based pattern to form a storage node contact hole; and forming a conductive layer and performing an etch-back process to form a storage node contact filled in the storage node contact hole.

### BRIEF DESCRIPTION OF THE DRAWINGS

FIG. 1 illustrates a micrographic view of a typical overlap configuration of a storage node hole with a storage node contact hole.

FIGS. 2A to 2D illustrate cross-sectional views showing a method for fabricating a semiconductor device in accordance with an embodiment of the present invention.

FIGS. 3A to 3C illustrate micrographic views showing a top portion of a storage node contact in accordance with an embodiment of the present invention.

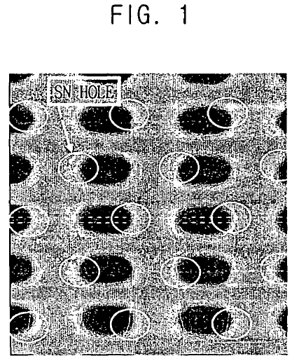

### DESCRIPTION OF SPECIFIC EMBODIMENTS

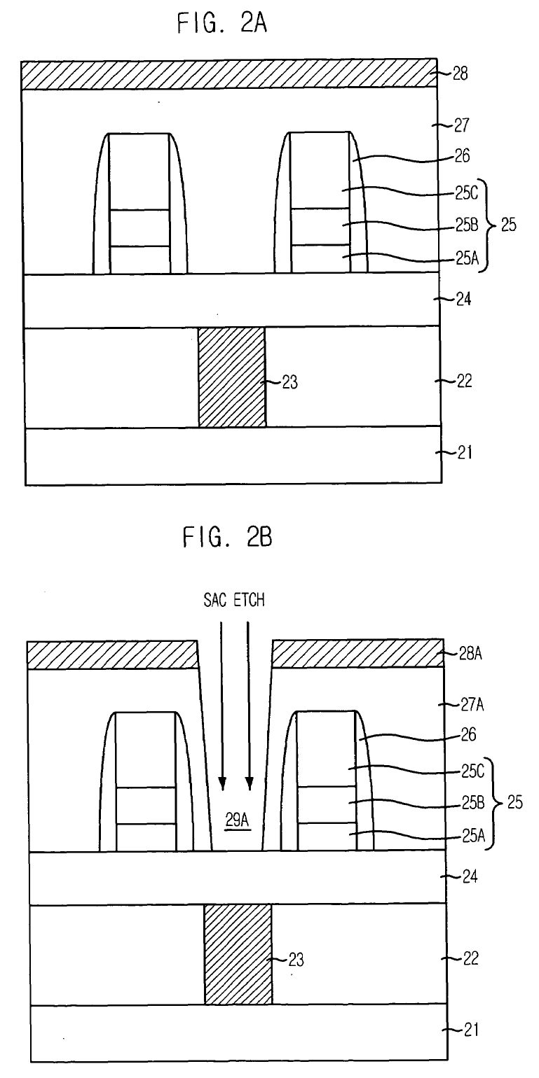

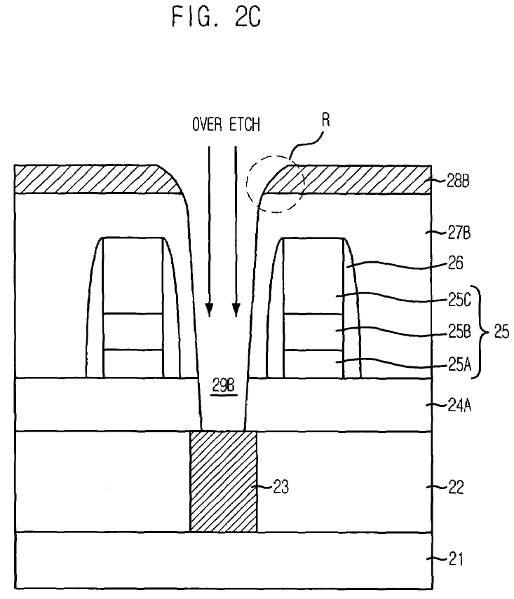

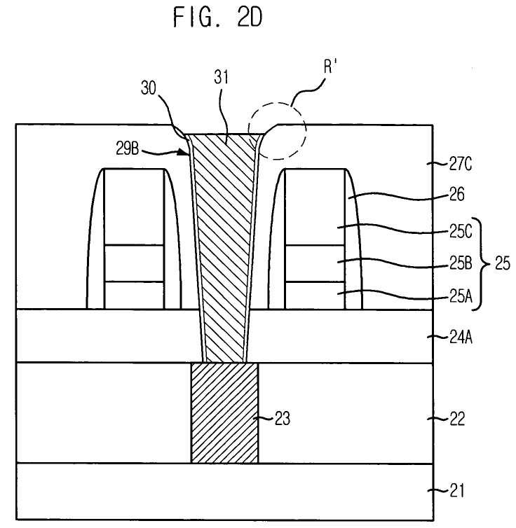

FIGS. 2A to 2D illustrate cross-sectional views showing a method for fabricating a semiconductor device in accordance with an embodiment of the present invention.

Referring to FIG. 2A, a bit line pattern 25 is formed over a substrate 21 which has undergone given processes. A landing plug contact 23, which is insulated from neighboring landing contact plugs 23 by virtue of a first insulation layer 22, is formed over a substrate 21. A second insulation layer 24 is formed over the landing plug contact 23 and the first insulation layer 22. A bit line pattern 25 configured with a Ti/TiN barrier metal 25A, a tungsten layer 25B and a hard mask layer 25C is formed over the second insulation layer 24. The hard mask layer 25C includes a nitride-based layer.

Bit line spacers 26 are formed on both sidewalls of the bit line pattern 25 through nitride deposition and etch-back processes. Over the resultant structure, a third insulation layer 27 is formed to insulate the bit line patterns 25. A hard mask nitride-based layer 28 is formed over the third insulation layer 27.

Referring to FIGS. 2B and 2C, storage node contact (SNC) etching is performed. To begin with, an anti-reflective layer (not shown) such as an organic bottom anti-reflective coating layer (OBARC) is formed over the hard mask nitride-based layer 28. A storage node contact mask (not shown) is formed using a photoresist layer. The anti-reflective layer and the hard mask nitride-based layer 28 are etched using the storage node contact mask (SNC mask) as an etch barrier to form a hard mask nitride-based pattern 28A. Then, the SNC mask is removed and etch residues such as polymers are removed. When the SNC mask is removed, the anti-reflective layer is also removed at the same time. The third insulation layer 27 is etched using the remaining hard mask nitride-based pattern 28A as an etch barrier to thereby form a first trench 29A between the bit line patterns 25. Reference denotation 27A represents a patterned third insulation layer. Herein, the first trench 29A is a preliminary trench for a storage node contact hole which will be formed later. The etching is performed under the condition that the third insulation layer 27 has high etch selectivity with respect to the hard mask nitride-based pattern 28A. This etching process is generally called a self-aligned contact (SAC) etch. While forming the first trench 29A, only the height of the hard mask nitride-based pattern 28A decreases.

Referring to FIG. 2C, a storage node contact overetch (SNC overetch) is further performed on the second insulation layer 24 to expose a top surface of the landing plug contact 23. Reference denotation 24A represents a patterned second insulation layer. As a result, a second trench 29B is formed such that the second trench 29B has a top corner with a rounded slope shape (see reference denotation R). Hereinafter, the second trench 29B is referred to as a storage node contact hole 29B, because the second trench 29B is used for forming a storage node contact.

In the SNC overetch, if the etch rate of the hard mask nitride-based pattern 28A is increased, the hard mask nitride-based pattern 28B becomes thinner and an edge thereof has a rounded slope shape after the forming of the second trench 29B is completed. Such an increase of etch rate of the hard mask nitride-based pattern can be achieved by decreasing a SAC performance, i.e., decreasing an etch selectivity of the second insulation layer with respect to the hard mask nitride-based pattern.

As illustrated above, the increase of the etch rate of the hard mask nitride-based pattern 28A causes an etch loss of the hard mask nitride-based pattern 28A. That is, the height of the hard mask nitride-based pattern 28A decreases and a portion of an edge of the hard mask nitride-based pattern 28A is also removed thereby forming a hard mask nitride-based pattern 28B having rounded top corners. At this time, a top portion of the storage node contact hole 29B also has a rounded slope shape (reference denotation R). Reference denotation 27B represents a rounded third insulation layer. A recipe for forming the rounded slope shape will be discussed in greater detail below.

Although the targets for the SAC etch and the overetch are divided based on the second insulation layer 24 in the embodiment, the SAC etch may be performed until the target (landing plug contact) is exposed and the overetch may be performed from the point that the target (landing plug contact) is exposed. Considering that a typical etching process includes a main etch and an overetch, the SAC etch may be considered as a main etch. Herein, the overetch is performed for etching residues produced by the main etch and obtaining etching uniformity.

Referring to FIG. 2D, a storage node contact spacer 30 is formed on both sidewalls of the storage node contact hole 29B through nitride deposition and etch-back processes. Then, a polysilicon layer is deposited on the resultant structure to fill the storage node contact hole 29B, and the etch-back is then performed to form a storage node contact 31 filling the storage node contact hole 29B.

While the storage node contact 31 is formed through etch-back, the top corner of the storage node contact hole 29B is still maintained to be a rounded slope shape. Thus, the top corner of the storage node contact hole 29B keeps the rounded slope shape even after the forming of the storage node contact 31 is completed. In addition, the top corner may be more rounded through etch-back for forming the storage node contact spacer 30 and the storage node contact 31 as represented with reference denotation R′. Reference denotation 27C represents a further rounded third insulation layer.

This rounded slope shape of the top portion of the storage node contact hole 29B provides a large area in comparison with the typical method. Thus, a contact area between the top portion of the storage node contact hole and a bottom portion of the storage node hole increases accordingly.

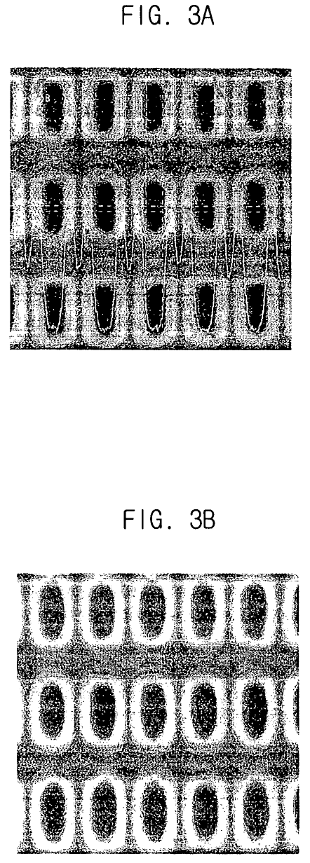

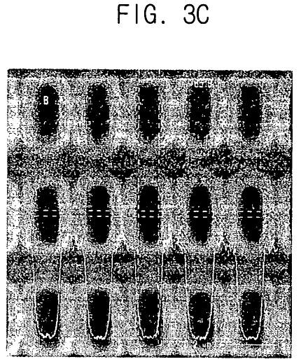

FIGS. 3A to 3C illustrate micrographic views showing a top portion of a storage node contact in accordance with an embodiment of the present invention. The top portion of the storage node contact shown in FIG. 3B has a wider and more rounded shape than that shown in FIG. 3A, and the top portion of the storage node contact shown in FIG. 3C has a wider and more rounded shape than that shown in FIG. 3B. A contact area between the storage node and the storage node contact may be more increased or more easily controlled appropriately as the top portion of the storage node contact obtains a wider and more rounded shape. To achieve such a result, in accordance with the present invention, a portion of the hard mask nitride-based pattern is also removed through the overetch which is performed for exposing a top surface of the landing plug contact after the main etch, i.e., the SAC etch.

The removal of the portion of the hard mask nitride-based pattern is performed using a following recipe. Etching is performed using a mixed gas of C₄F₆ gas, oxygen (O₂) gas and argon (Ar) gas, and radio frequency (RF) power plasma on condition that SAC atmosphere is reduced in order to decrease the generation of polymers. This causes partial loss of the hard mask nitride-based pattern, and thus the hard mask nitride-based pattern has the rounded slope shape. Recipes for the SAC etch and the overetch in accordance with the embodiment of the present invention will be described below.

The SAC etch, i.e., main etch, uses an etching gas including C₄F₆ and O₂. A flow rate ratio of C₄F₆ to O₂ ranges from approximately 1.01-2:1. Ar gas is added as dilution gas, and a total flow rate of a mixed gas ranges from approximately 20 sccm to approximately 200 sccm. During the SAC etch, source power is greater than bias power. The overetch uses an etching gas including C₄F₆ and O₂. A flow rate ratio of C₄F₆ to O₂ ranges from approximately 1:1.01-2. A total flow rate of a mixed gas ranges from approximately 20 sccm to approximately 200 sccm. During the overetch, bias power is greater than source power. C₄F₆ gas is a gas for deriving polymer generation and controlling the etch selectivity during the SAC etch and the overetch.

In the SAC etch, the flow rate of C₄F₆ is greater than that of O₂, and Ar dilution gas with high flow rate is added to keep the condition of abundant polymers under SAC atmosphere. That is, ratio of C₄F₆ to O₂ ranges from approximately 1.01-2:1 to generate abundant polymers. In addition, source power is greater than bias power to generate more abundant polymers. Resultantly, etch selectivity between the insulation layer and the hard mask nitride-based pattern in the SAC etch is very high, ranging from approximately 50-70:1.

On the contrary, in the overetch, the flow rate of O₂ is greater than that of C₄F₆, but total flow rate of the mixed gas is equal to that in a SAC etch. In addition, bias power is greater than source power. Resultantly, etch selectivity between the insulation layer and the hard mask nitride-based pattern in the overetch is lower than the etch selectivity in the SAC etch, ranging from approximately 30-50:1.

As described above, if a large amount of C₄F₆ gas is used in the SAC etch but a small amount of C₄F₆ gas is used in the overetch, SAC atmosphere could be reduced and polymer generation could be decreased. For reference, if polymer generation is decreased, the etch loss of the hard mask nitride-based pattern can be generated. Contrariwise, if polymer generation is increased, abundant polymers restrain the hard mask nitride-based pattern from being lost. In the typical method, the loss of a hard mask nitride-based pattern does not occur, because only the SAC etch is performed.

The hard mask nitride-based pattern with the rounded slope shape could be obtained after the overetch based on the above condition. The nitride deposition and etch-back processes are performed to form the storage node contact spacer 30, and thereafter the polysilicon deposition and etch-back processes are performed to form the storage node contact 31. Accordingly, the rounded slope shape of the top portion of the storage node contact hole 29B is transferred such that the top area of the storage node contact hole 29B increases compared with the typical case and thus a contact area between the storage node contact and the storage node increases.

Although the method for increasing the contact area between the storage node contact and the storage node is illustrated in the embodiment, the inventive method can be applied to a method for increasing a contact area between a contact plug filling a contact hole and interconnections connected thereto, e.g., metal interconnections, in the semiconductor device.

In accordance with the present invention, a shape of an edge of the hard mask nitride-based pattern is controlled while forming a storage node contact hole so that a contact margin between the top portion of the storage node contact hole and the bottom portion of a storage node hole is increased. Thus, the present invention provides an advantageous effect of preventing an open fail between the storage node contact and the storage node.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming an insulation layer over a substrate having a given structure;
forming a hard mask pattern over the insulation layer;
performing a main etch on the insulation layer with a high etch selectivity with respect to a hard mask pattern to form a preliminary contact hole;
performing an overetch on the insulation layer with a low etch selectivity with respect to a hard mask pattern to form a contact hole; and
forming a conductive layer and performing an etch-back process to form a contact filled in the contact hole.

2. The method of claim 1, wherein a mixed gas including a first gas and a second gas is used as an etch gas for the main etch and the overetch, the second gas inducing polymer generation to control an etch selectivity with respect to the hard mask pattern.

3. The method of claim 2, wherein a flow rate of the second gas is greater than that of the first gas during the main etch to increase the etch selectivity with respect to the hard mask pattern and a flow rate of the second gas is smaller than that of the first gas during the overetch to decrease the etch selectivity with respect to the hard mask pattern.

4. The method of claim 3, wherein source power and bias power are simultaneously used during the main etch and the overetch.

5. The method of claim 4, wherein the source power is greater than the bias power during the main etch to increase the etch selectivity with respect to the hard mask pattern, and the bias power is greater than the source power during the overetch to decrease the etch selectivity with respect to the hard mask pattern.

6. A method for fabricating a semiconductor device, comprising:
forming an oxide layer for insulation over a substrate having a given structure;
forming a hard mask nitride-based pattern over the oxide layer;
performing a main etch on the oxide layer with a high etch selectivity with respect to the hard mask nitride-based pattern to form a preliminary storage node contact hole;
performing an overetch on the oxide layer with a low etch selectivity with respect to a hard mask nitride-based pattern to form a storage node contact hole; and
forming a conductive layer and performing an etch-back process to form a storage node contact filled in the storage node contact hole.

7. The method of claim 6, wherein a mixed gas including a first gas and a second gas is used as an etch gas for the main etch and the overetch, the second gas inducing polymer generation to control an etch selectivity with respect to the hard mask nitride-based pattern.

8. The method of claim 7, wherein a flow rate of the second gas is greater than that of the first gas during the main etch to increase the etch selectivity with respect to the hard mask nitride-based pattern and a flow rate of the second gas is smaller than that of the first gas during the overetch to decrease the etch selectivity with respect to the hard mask nitride-based pattern.

9. The method of claim 8, wherein the second gas includes C₄F₆ gas and the first gas includes oxygen (O₂) gas.

10. The method of claim 9, wherein a flow rate ratio of C₄F₆ gas to O₂ gas ranges from approximately 1.01-2:1 to increase the etch selectivity with respect to the hard mask nitride-based pattern.

11. The method of claim 10, wherein a flow rate ratio of C₄F₆ gas to O₂ gas ranges from approximately 1:1.01-2 to decrease the etch selectivity with respect to the hard mask nitride-based pattern.

12. The method of claim 7, wherein source power and bias power are simultaneously used for the main etch and the overetch.

13. The method of claim 12, wherein the source power is greater than the bias power during the main etch to increase the etch selectivity of the hard mask nitride-based pattern, and the bias power is greater than the source power during the overetch to decrease the etch selectivity of the hard mask nitride-based pattern.

14. The method of claim 13, wherein the etch selectivity between the oxide layer and the hard mask nitride-based pattern ranges from approximately 50-70:1 during the main etch.

15. The method of claim 14, wherein the etch selectivity between the oxide layer and the hard mask nitride-based pattern ranges from approximately 30-50:1 during the overetch.
